(19) United States
(12) Patent Application Publication
(10) Pub. No.: US 2017/0184631 A1
(43) Pub. Date: Jun. 29, 2017

(54) PROBE DEVICE FOR SCANNING PROBE MICROSCOPES AND METHOD OF MANUFACTURE THEREOF

(71) Applicant: Applied Nanostructures, Inc., Mountain View, CA (US)

(72) Inventors: Ami Chand, Milpitas, CA (US); Jeremy Goeckeritz, San Jose, CA (US)

(21) Appl. No.: 15/378,879

(22) Filed: Dec. 14, 2016

Related U.S. Application Data
(60) Provisional application No. 62/267,207, filed on Dec. 14, 2015.
(60) Provisional application No. 62/267,713, filed on Dec. 15, 2015.

(51) Int. Cl. G01Q 70/14; H01L 21/311

(52) U.S. Cl. CPC G01Q 70/14; H01L 21/31111; H01L 21/31116

(57) ABSTRACT

Specific probe device configurations and processes for producing those probe configurations. A Probe device may include a silicon nitride cantilever of controlled thickness, holding a silicon probe tip of controllable sharpness. The probe tip may also be coated with a silicon nitride layer also of controllable thickness. An optional silicon reflective pad may also be formed as a base for the tip. The probe device is produced by forming a tip, optionally with base pad, on a silicon wafer, depositing a silicon nitride film on the wafer, etching the silicon nitride film to form a cantilever holding the tip/pad, selectively etching the silicon nitride film for separately controllable thickness both for the cantilever and the coated tip, and then etching away the backside silicon to leave a free silicon nitride cantilever holding a silicon nitride coated tip.

### BACKGROUND

The specification relates to probe devices for Scanning Probe Microscopes (SPMs) and in particular to a probe that combines the benefit of ilicon itride cantilevr and silicon tip aspects in one probe design.

SPMs generally include scanning, and probe deflection elements that position/scan a probe device relative to a sample with sub-nanometer precision and measure the interaction of the probe device with the sample using a deflection detector with angstrom precision. Thus sample information and/or maps of the sample may be produced with sub nanometer accuracy. The probe devices typically are some sort of deflectable structure, such as a cantilever or other flexure structure with dimensions ranging from few microns to tens of microns. Probe devices also often include a probe tip extending out of the plane of the flexure element (cantilever) with a very sharp tip end. These probe devices generally are disposable devices, and produced in bulk using microfabrication techniques similar to those used for microelectronic devices. Thus probe devices are often based on silicon wafer processing and are constructed from combinations of silicon and/or deposited films of silicon processing compatible materials. Depending on the type of sample being scanned, specific probe parameters such as cantilever stiffness, probe tip sharpness and probe tip material and others may be suitable for one application and not for others.

### SUMMARY

In some embodiments, specific probe device configurations and processes for producing those probe configurations may be provided. A Probe device may include a silicon nitride cantilever of controlled thickness, holding a silicon probe tip of controllable sharpness. The probe tip may also be coated with a silicon nitride layer also of controllable thickness. An optional silicon reflective pad may also be formed as a base for the tip. The probe device is produced by forming a tip, optionally with base pad, on a silicon wafer, depositing a silicon nitride film on the wafer, etching the silicon nitride film to form cantilever holding the tip/pad, electively etching the silicon nitride film for separately controllable thickness both for the cantilever and the coated tip, and then etching away the backside silicon to leave a free silicon nitride cantilever holding a silicon nitride coated tip.

In a first aspect, a probe device for a scanning probe microscope may be provided, including a silicon nitride cantilever, and a silicon tip coated with deposited silicon nitride. In one embodiment of the first aspect, the device may include a silicon pad configured to be reflective to light from an optical deflection detector. In another embodiment of the first aspect, the cantilever thickness may be determined by a silicon nitride deposition process.

In one embodiment of the first aspect, the cantilever thickness may be between 30 nanometer (nm) and 1500 nanometer (nm). In one embodiment of the first aspect, the cantilever thickness may be between 200 and 600 nanometers. In another embodiment of the first aspect, the deposited silicon nitride coating may be between 5 nanometer (nm) and 1500 (nm) nanometer. In one embodiment of the first aspect, the tip diameter may be controlled by selectively etching the deposited silicon nitride coating. In another embodiment of the first aspect, the tip diameter may be between 10 nanometers and 1 micrometer (μm). In one embodiment of the first aspect, a single layer of silicon nitride may be deposited to provide the cantilever and tip coating and complete the probe.

In a second aspect, a process for making a probe device for a scanning probe microscope may be provided, including: forming a silicon tip on a silicon wafer; depositing silicon nitride to form cantilever attached to the silicon tip and coating the tip; etching deposited silicon nitride selectively to form cantilever with sharpened tip; etching backside silicon selectively to remove silicon from cantilever, leaving silicon tip and, etching the front and back side silicon nitride selectively to free cantilever.

In one embodiment of the second aspect, the process may further include forming a silicon pad at the base of the tip. In another embodiment of the second aspect, the process may further include growing an oxide layer on the silicon tip prior to silicon nitride deposition. In one embodiment of the second aspect, the cantilever thickness may be determined by the silicon nitride deposition process.

In another embodiment of the second aspect, the cantilever thickness may be between 5 nanometers and 1500 nanometers. In one embodiment of the second aspect, the cantilever thickness may be between 200 and 600 nanometers. In another embodiment of the second aspect, the deposited silicon nitride coating may be between 5 nanometers and 1500 nanometers.

In one embodiment of the second aspect, the tip diameter may be controlled by selectively etching the deposited silicon nitride coating. In another embodiment of the second aspect, the tip diameter may be between 1 nanometer and 1 micron. In one embodiment of the second aspect, a single layer of silicon nitride may be deposited to provide the coating and complete the probe. In another embodiment of the second aspect, the process may further include selectively etching the silicon of the free cantilever creating a hollow silicon nitride tip.

### BRIEF DESCRIPTION OF THE DRAWINGS

Aspects and advantages of the embodiments provided herein are described with reference to the following detailed description in conjunction with the accompanying drawings. Throughout the drawings, reference numbers may be re-used to indicate correspondence between referenced elements. The drawings are provided to illustrate example embodiments described herein and are not intended to limit the scope of the disclosure.

FIGS. 1A, 1B, 1C, 1D, 1E, and 1F show process steps of an example embodiment.

FIG. 2 shows an alternative process step for an example embodiment.

FIG. 3 shows a probe device produced by the above process steps according to an example embodiment.

FIG. 4 is another view of a probe device.

FIG. 5 shows results achieved on a biological sample.

FIG. 6 is a flow chart of process steps of an example embodiment.

### DETAILED DESCRIPTION OF ILLUSTRATIVE EMBODIMENTS

In general, the present disclosure relates to combining a silicon probe tip with a silicon nitride cantilever to produce a probe device for SPM's, with the silicon probe tip further coated with a silicon nitride layer. This device provides the advantages of a silicon nitride cantilever, which is less stiff then a silicon cantilever, and therefore more suitable for soft sample application such as scanning biological materials. Moreover, the device provides a silicon probe tip, which may be sharper than a silicon nitride tip, or a silicon probe tip coated with silicon nitride, which is better suited for some biological applications compared to bare silicon. In particular the processing employed allows for a great deal of flexibility in configuring the probe device for specific sample applications. Cantilever thickness, which relates the stiffness of the cantilever may be controlled independently from tip sharpness for instance. Since silicon and silicon nitride have different optical properties, the optical characteristics of the probe device may selectively controlled.

One or more embodiments may provide for low cost of manufacturing. Advantageously single silicon nitride layer for cantilever, tip and backside etch may create a holding chip.

One or more embodiments may provide for a silicon reflective surface on the cantilever backside. Advantageously no metal coating is necessary which is simpler to process and less prone to thermal drift.

One or more embodiments may provide for flexibility in tip sharpness. Advantageously both sharp and dull tips coated with silicon nitride are achievable.

One or more embodiments may provide for low stiffness cantilevers with sharp silicon nitride surface tips. Advantageously such a probe device is well-suited for biological sample applications.

Scanning Probe cantilevers made out of silicon nitride may require a metal reflective coating for use with optical deflection detectors in Scanning Probe Microscopes. Silicon nitride is transparent to the light sources in many optical deflection detectors. The metal and silicon nitride material have different thermal expansion coefficients. This can cause the cantilever to bend when immersed in liquid for imaging biological samples. In these silicon nitride probes having silicon nitride tips, the tip height is typically 2 μm to 12 μm. Since these tips are made using a silicon mold, the tip aspect ratio is very poor due to the large opening angles at the base. The opening angle is determined by 111 plane of the 100 silicon wafer wafer (54.7 degree). These tips, made out of the mold, may be difficult to make as sharp as desired for many applications. It is desirable to get an inverted pyramid where all four sides meet at a single point. This requires defining a highly accurate square using lithography. The sides of the squares should be about 25 μm for a tip height of 18 μm. In order to get a consistent tip sharpness of 30 nm, both sides of the square should be within 50 nm of each other. Using microfabrication techniques employed for making small mechanical devices such as SPM probes it may not be practical to achieve this.

Therefore it is difficult to make a satisfactory probe tip out of silicon nitride, but silicon nitride is a useful material for the cantilever arm portion of the probe for may probing applications as silicon nitride cantilevers may be made relatively pliant which is suitable for applications such as biological material probing. Silicon tips may be made sharper, higher aspect ratio, and taller more easily than silicon nitride tips, but silicon cantilever arms tend to be stiffer and less pliant than silicon nitride cantilever arms.

Silicon tips with silicon nitride cantilevers may be made of a silicon pyramid embedded in and protruding above the surface of a silicon nitride body. However even with a silicon nitride cantilever, silicon tips may not be desirable for some applications including some biological samples many of the biological experiments give better results with a silicon nitride surface on the tip to interact with the sample. However the required tip height is more than 15 um to 20 um to image high topographic biological samples, which is difficult to achieve with a all silicon nitride process.

A probe device according to present disclosure will have the following features:

The cantilever is made of silicon nitride. Cantilever thickness is determined by the deposition process and can be varied from 30 nm to 1500 nm. Most commonly used cantilevers are 200 nm to 600 nm thick.

An embedded silicon tip is completely covered with silicon nitride. Even though the silicon nitride material for the tip and cantilever is deposited in the same step, the tip coating thickness is independently controlled to make a sharp or dull tip. A sharper tip may have a thickness of silicon nitride around 5 nm. A less sharp tip may be covered by silicon nitride as thick as the thickness of the cantilever or more as thermal oxidation under the silicon nitride layer may be grown. This makes the tip design quite flexible with sharpness ranging from as sharp as 10 nm to greater than 1 μm.

In some embodiments the silicon tip may be integrated with a non-transparent silicon base pad to reflect the optical deflection light source from the probe when the SPM is imaging. This approach to achieving reflection cantilever does not cause bending when imaging a sample in liquid environment as does reflective metal coatings.

The process of manufacturing is simplified to reduce cost of manufacturing and with increased reliability. In some embodiments a single layer of silicon nitride is deposited to complete the devices and still maintain the flexibility of design. Both front and backside etching may be employed in the manufacturing.

An exemplary process embodiment to produce the novel probe device will now be described. It is understood that the process described is a wafer scale micromachining process, and that the structure shown and described is one die, repeated many time across a wafer such that a large number (dependent on wafer size and die size) of die are processes in parallel across the wafer.

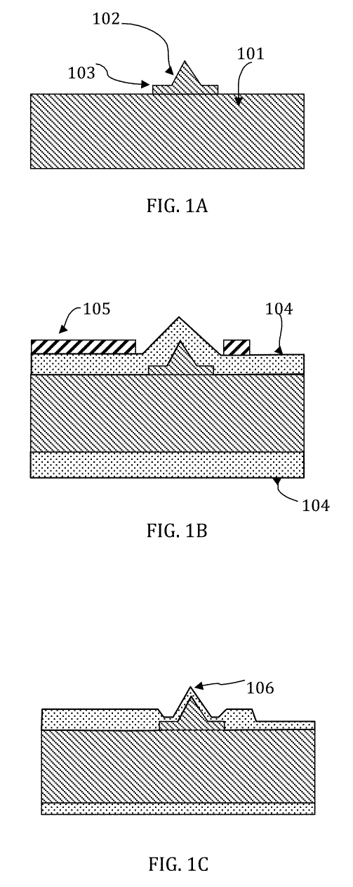

Referring to FIG. 1A, a silicon probe tip is 102 formed from a silicon wafer 101 by masking and wet or dry anisotropic etching processes. An optional reflective pad 103 may be formed as well. At this point it is optional to grow silicon dioxide layer on the silicon (not shown). Silicon Nitride layer 104 is then deposited on the wafer. Normally this is a super low stress nitride deposited using low pressure chemical vapor deposition (CVD) techniques. The silicon nitride layer is deposited on both sides of the wafer. The thickness of the later is kept slightly more than the required thickness of the cantilever. This biased thickness is important keep a desired thickness of silicon nitride on the tip and free release the cantilever.

A cantilever pattern that excludes the tip is then defined in a masking layer 105 of photoresist as shown in FIG. 1B. Alternative masking layers could be made of CVD metal or silicon dioxide. This will leave a layer of silicon nitride of controlled thickness, optionally thinner compared to the cantilever thickness, on top of the tip 102, pad 103 and around the holding chip 108. The remaining silicon nitride thickness 106 should be more than the final desired thickness. Half of this layer will be etched at the end of the process. This step determines the final tip diameter. The masking layer is then removed. The cross-sectional view at this step is shown in FIG. 1C. FIG. 1D shows a top view of a single probe defined in silicon nitride layer 104 containing cantilever 105, holding chip body 108 and open area 107 around the chip body. The open area is made of thinner silicon nitride layer that will be etched away in the final step of processing.

FIG. 1E top shows several device die on the wafer. The probe body frame is defined on the backside (opposite side of the tip) such that desired length of the cantilever is achieved. The silicon nitride 104 is etched selectively until the underlying silicon surface is exposed from the areas not covered by the mask. The silicon is then etched away to the silicon nitride in the cantilever area, leaving the silicon tip backside 110 and silicon holding chip 108. The cross-section at this stage is shown in the FIG. 1E (bottom). This results in a probe surrounded by a membrane 109 of silicon nitride. Then the silicon nitride membrane 109 is etched to release the cantilever. The silicon nitride membrane 109 is etched from the front and backside whereas the silicon nitride at the tip is etched only from the front side, thereby allowing the membrane to be removed before completely etching the tip silicon nitride. This is shown in FIG. 1F. The backside of the tip 110 may be used as pad to reflect laser for imaging the samples in a scanning probe microscope. Optionally the probes may be coated with metal layer.

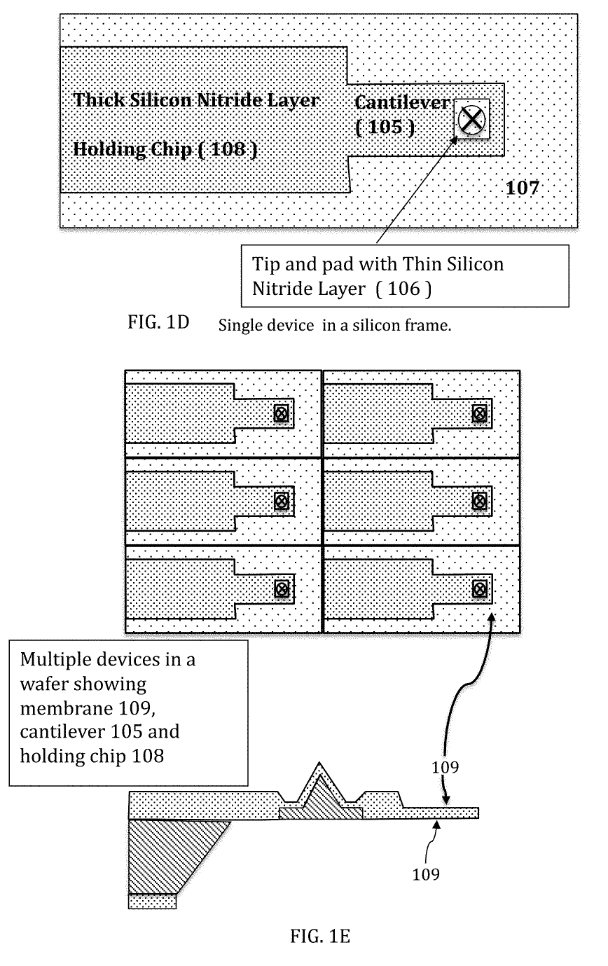

FIG. 2 shows the final released device using an alternative process based on silicon-on-Insulator (SOI) wafer. The cross-sectional view also depicts an additional layer of silicon dioxide 111 between the tip and the silicon nitride layer. Silicon dioxide is etched if it is used. Optionally the probes may be coated with a metal layer.

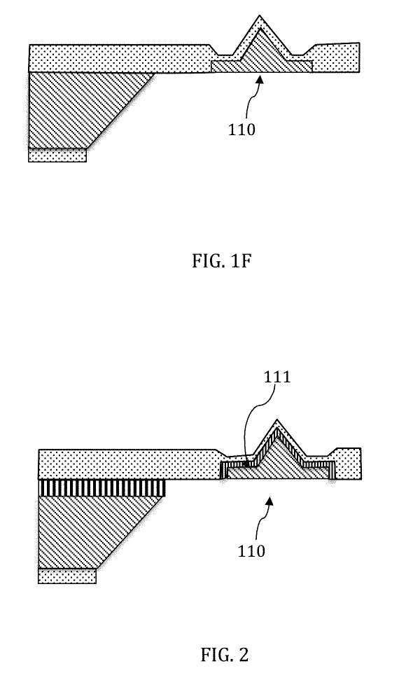

FIG. 3 shows a completed, released probe device.

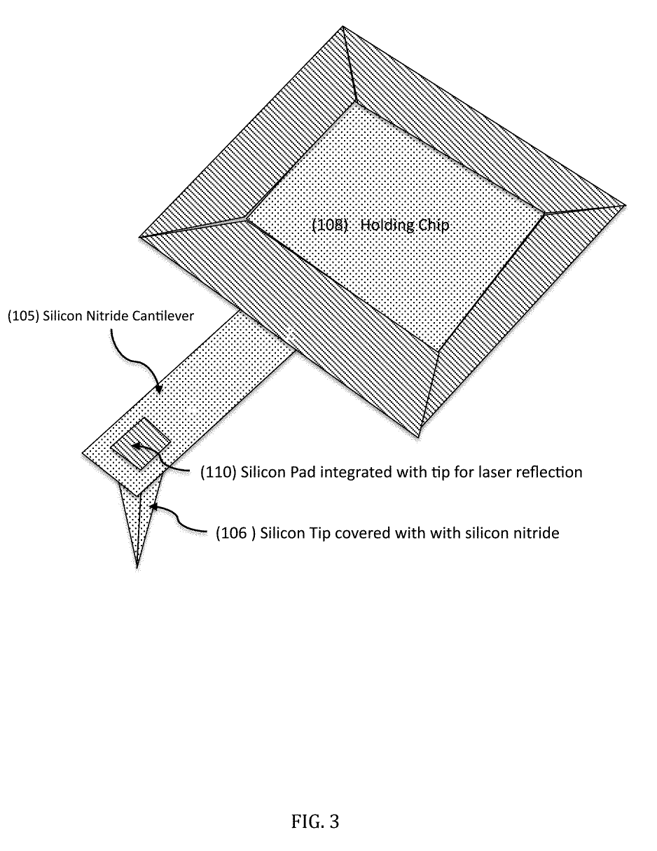

FIG. 4 also depicts an actual device consisting of silicon nitride cantilever, silicon nitride tip with silicon integrated pad.

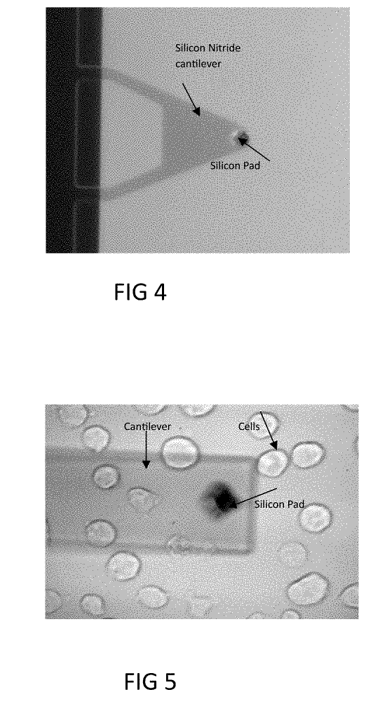

FIG. 5 shows image of a device while imaging the tall bio-cells.

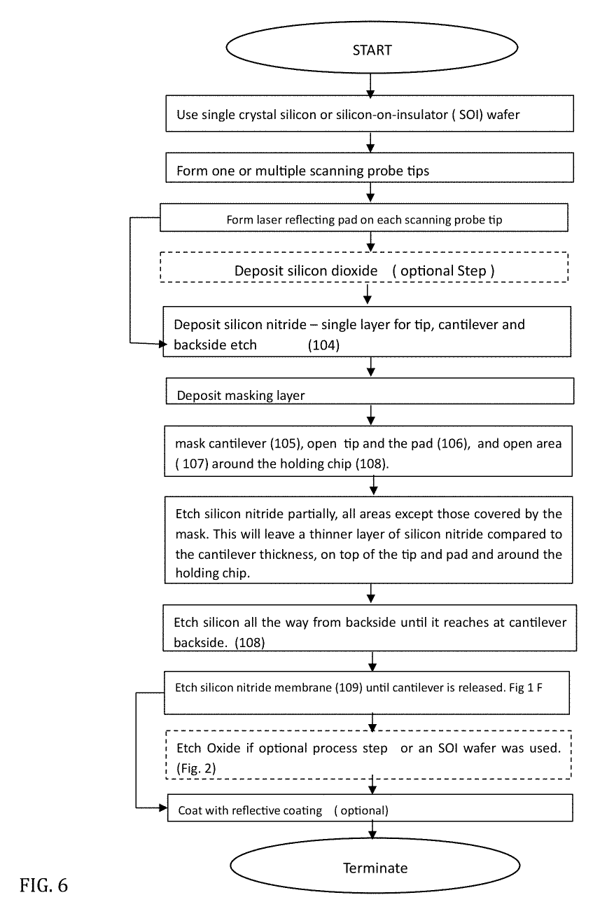

FIG. 6 shows the example process of FIGS. 1A-1F and 2 in flow chart form

The embodiments described herein are exemplary. Modifications, rearrangements, substitute processes, alternative elements, etc. may be made to these embodiments and still be encompassed within the teachings set forth herein. One or more of the steps, processes, or methods described herein may be carried out by one or more processing elements used in microfabrication.

Depending on the embodiment, certain acts, events, or functions of any of the method steps described herein can be performed in a different sequence, can be added, merged, or left out altogether (e.g., not all described acts or events are necessary for the practice of the algorithm). Moreover, in certain embodiments, acts or events can be performed concurrently, rather than sequentially.

The various processing steps and materials are related to microfabrication, and include various microfabrication processes, such as photolithography, deposition, planarization, etching, both plasma and wet etch, implanting and others and apply to silicon wafer scale processing in a variety of wafer sizes and critical dimension regimes. Materials involve photomask materials, thin film materials such as metals, silicon nitride and silicon oxides, silicon, etching agents, cleaning agents and others. Any combination of processes and materials suitable for the desired resultant device may be employed

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment. The terms “comprising,” “including,” “having,” “involving,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y or Z,” unless specifically stated otherwise, is otherwise understood with the context as used in general to present that an item, term, etc., may be either X, Y or Z, or any combination thereof (e.g., X, Y and/or Z). Thus, such disjunctive language is not generally intended to, and should not, imply that certain embodiments require at least one of X, at least one of Y or at least one of Z to each be present.

The terms “about” or “approximate” and the like are synonymous and are used to indicate that the value modified by the term has an understood range associated with it, where the range can be ±20%, ±15%, ±10%, ±5%, or ±1%. The term “substantially” is used to indicate that a result (e.g., measurement value) is close to a targeted value, where close can mean, for example, the result is within 80% of the value, within 90% of the value, within 95% of the value, or within 99% of the value.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

While the above detailed description has shown, described, and pointed out novel features as applied to illustrative embodiments, it will be understood that various omissions, substitutions, and changes in the form and details of the devices or methods illustrated can be made without departing from the spirit of the disclosure. As will be recognized, certain embodiments described herein can be embodied within a form that does not provide all of the features and benefits set forth herein, as some features can be used or practiced separately from others. All changes which come within the meaning and range of equivalency of the claims are to be embraced within their scope.

We claim:

1. A probe device for a scanning probe microscope, comprising:
a silicon nitride cantilever, and
a silicon tip coated with deposited silicon nitride.

2. The device of claim 1 further comprising a silicon pad configured to be reflective to light from an optical deflection detector.

3. The device of claim 1 wherein the cantilever thickness is determined by a silicon nitride deposition process.

4. The device of claim 3 wherein the cantilever thickness is between 30 and 1500 nanometers.

5. The device of claim 3 wherein the cantilever thickness is between 200 and 600 nanometers.

6. The device of claim 1 wherein the deposited silicon nitride coating is between 5 and 1500 nanometers.

7. The device of claim 6 wherein the tip diameter is controlled by selectively etching the deposited silicon nitride coating.

8. The device of claim 7 wherein the tip diameter is between 10 nanometers and 1 micron.

9. The device of claim 1 wherein a single layer of silicon nitride is deposited to provide the coating and complete the probe.

10. A process for making a probe device for a scanning probe microscope, comprising;
forming a silicon tip on a silicon wafer;
depositing silicon nitride to form cantilever attached to the silicon tip and coating the tip;
etching deposited silicon nitride selectively to form cantilever with sharpened tip;
etching backside silicon selectively to remove silicon from cantilever, leaving silicon tip and,
etching front side silicon nitride selectively to free cantilever.

11. The process of claim 10 further comprising forming a silicon pad at the base of the tip.

12. The process of claim 10 further comprising growing an oxide layer on the silicon tip prior to silicon nitride deposition.

13. The process of claim 10 wherein the cantilever thickness is determined by the silicon nitride deposition process.

14. The process of claim 13 wherein the cantilever thickness is between 30 and 1500 nanometers.

15. The process of claim 13 wherein the cantilever thickness is between 200 and 600 nanometers.

16. The process of claim 10 wherein the deposited silicon nitride coating is between 5 and 1500 nanometers.

17. The process of claim 16 wherein the tip diameter is controlled by selectively etching the deposited silicon nitride coating.

18. The process of claim 17 wherein the tip diameter is between 10 nanometers and 1 micron.

19. The process of claim 10 wherein a single layer of silicon nitride is deposited to provide the coating and complete the probe.

20. The process of claim 10 further comprising selectively etching the silicon of the free cantilever creating a hollow silicon nitride tip.
